(19) United States
(12) Patent Application Publication
(10) Pub. No.: US 2025/0216779 A1
(43) Pub. Date: Jul. 3, 2025

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Sanghee JANG, Suwon-si (KR); Miyeon HAN, Suwon-si (KR); Seung-Wook SHIN, Suwon-si (KR); Jaeyeol BAEK, Suwon-si (KR)

(21) Appl. No.: 18/951,304

(22) Filed: Nov. 18, 2024

(30) Foreign Application Priority Data
Jan. 3, 2024 (KR) 10-2024-0001129

(51) Int. Cl. G03F 7/004; G03F 1/80

(52) U.S. Cl. CPC G03F 7/0043; G03F 1/80

(57) ABSTRACT

Disclosed are a semiconductor photoresist composition and a method of forming patterns using the same, the semiconductor photoresist composition including an Sn-containing organometallic compound; a carboxylic acid compound; at least one selected from a sulfonic acid compound and a phosphonic acid compound; and a solvent.

### CROSS-REFERENCE TO RELATED APPLICATION

The present application claims priority to and the benefit of Korean Patent Application No. 10-2024-0001129, filed on Jan. 3, 2024, in the Korean Intellectual Property Office, the entire content of which is hereby incorporated by reference.

### BACKGROUND

### 1. Field

Embodiments of this disclosure relate to semiconductor photoresist compositions and methods of forming patterns using the same.

### 2. Description of the Related Art

EUV (extreme ultraviolet) lithography has been paid attention to as one technology for manufacturing a next generation semiconductor device. EUV lithography is a pattern-forming technology using an EUV ray having a wavelength of 13.5 nm as an exposure light source. According to EUV lithography, an extremely fine pattern (e.g., less than or equal to 20 nm) may be formed in an exposure process during a manufacture of a semiconductor device.

EUV lithography is realized through development of compatible photoresists which can be performed at a spatial resolution of less than or equal to 16 nm. Currently, efforts to satisfy insufficient specifications of traditional chemically amplified (CA) photoresists such as a resolution, a photospeed, and feature roughness (which may also be referred to as a line edge roughness or LER) for next generation devices are being made.

An intrinsic image blurring due to an acid catalyzed reaction in polymer-type photoresists limits a resolution in small feature sizes, which has been present in electron beam (e-beam) lithography. CA photoresists are designed for high sensitivity, but because their typical elemental makeups reduce light absorbance of the photoresists at a wavelength of 13.5 nm and thus decrease their sensitivity, CA photoresists may partially have more difficulties under an EUV exposure.

CA photoresists may have difficulties with respect to small feature sizes due to roughness issues, and line edge roughness (LER) of CA photoresists experimentally turns out to be increased, as a photospeed is decreased partially due to features of acid catalyst processes. Accordingly, a high-performance photoresist for the semiconductor industry would be beneficial because of the foregoing defects and problems of the CA photoresists.

In order to overcome the aforementioned drawbacks of chemically amplified (CA) organic photosensitive compositions, an inorganic photosensitive composition has been researched. Inorganic photosensitive compositions are mainly used for negative tone patterning having resistance against removal by a developer composition due to chemical modification through a nonchemical amplification mechanism. Such inorganic compositions contain an inorganic element having a higher EUV absorption rate than hydrocarbons and thus may secure sensitivity through a nonchemical amplification mechanism and may be less sensitive with respect to a stochastic effect and thus have low line edge roughness and a relatively smaller number of defects.

Inorganic photoresists based on peroxopolyacids of tungsten mixed together with tungsten, niobium, titanium, and/or tantalum have been reported as radiation sensitive materials for patterning.

The foregoing materials are effective for patterning large pitches for bilayer configuration for far ultraviolet (deep UV), X-ray, and electron beam sources. More recently, when cationic hafnium metal oxide sulfate (HfSOx) materials along with a peroxo complexing agent has been used to image a 15 nm half-pitch (HP) through projection EUV exposure, impressive performance has been obtained. The aforementioned system exhibits the highest performance of a non-CA photoresist and has a practicable photospeed near to a requirement for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a TMAH (tetramethylammonium hydroxide) solution at an extremely high concentration of 25 wt % and/or the like.

Recently, active research has been conducted for molecules containing tin that have excellent absorption of extreme ultraviolet rays. As for an organotin polymer among them, alkyl ligands are dissociated by light absorption and/or secondary electrons produced thereby, and are crosslinked with adjacent chains through oxo bonds and thus enable the negative tone patterning which may not be removed by an organic developer. This organotin polymer exhibits greatly improved sensitivity as well as maintains a resolution and line edge roughness, but it would be beneficial to further improve patterning characteristics for commercial availability.

### SUMMARY

Some embodiments provide a semiconductor photoresist composition having excellent sensitivity and line edge roughness (LER) characteristics and improved sensitivity.

Some embodiments provide a method of forming patterns using the semiconductor photoresist composition.

A semiconductor photoresist composition according to some embodiments includes an Sn-containing organometallic compound; a carboxylic acid compound; at least one selected from a sulfonic acid compound and a phosphonic acid compound; and a solvent.

A method of forming patterns according to some embodiments includes providing an etching-objective film on a substrate, coating the semiconductor photoresist composition on the etching-objective film to form a photoresist film, patterning the photoresist film to form a photoresist pattern, and etching the etching-objective film using the photoresist pattern as an etching mask.

The semiconductor photoresist composition according to some embodiments enables excellent sensitivity and excellent LER characteristics.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1-5 are cross-sectional views illustrating a method of forming patterns using a semiconductor photoresist composition according to some embodiments.

### DETAILED DESCRIPTION

Hereinafter, referring to the drawings, embodiments of the present disclosure are described in more detail. In the following description of the subject matter of the present disclosure, the well-known functions or constructions will not be described in order to clarify the subject matter of the present disclosure.

In order to clearly illustrate the subject matter of the present disclosure, certain description and relationships may be omitted, and throughout the disclosure, the same or similar configuration elements are designated by the same reference numerals. Also, because the size and thickness of each configuration shown in the drawing may be arbitrarily shown for better understanding and ease of description, the present disclosure is not necessarily limited thereto.

In the drawings, the thickness of layers, films, panels, regions, etc., may be enlarged for clarity. In the drawings, the thickness of a part of layers or regions, etc., may be exaggerated for clarity. It will be understood that when an element such as a layer, film, region, or substrate is referred to as being “on” another element, it can be directly on the other element or intervening elements may also be present.

As used herein, “substituted” refers to replacement of a hydrogen atom by deuterium, a halogen, a hydroxy group, a carboxyl group, a thiol group, a cyano group, a nitro group, —NRR′ (wherein R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, when a definition is not otherwise provided, “alkyl group” refers to a linear or branched aliphatic hydrocarbon group. The alkyl group may be “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, when a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but is not limited thereto.

As used herein, “aliphatic unsaturated organic group” refers to a hydrocarbon group including a bond in which a bond between one carbon atom and another carbon atom in the referenced molecule is a double bond, a triple bond, or a combination thereof.

The aliphatic unsaturated organic group may be a C2 to C8 aliphatic unsaturated organic group. For example, the aliphatic unsaturated organic group may be a C2 to C7 aliphatic unsaturated organic group, a C2 to C6 aliphatic unsaturated organic group, a C2 to C5 aliphatic unsaturated organic group, or a C2 to C4 aliphatic unsaturated organic group. For example, the C2 to C4 aliphatic unsaturated organic group may be a vinyl group, an ethynyl group, an allyl group, a 1-propenyl group, a 1-methyl-1-propenyl group, a 2-propenyl group, a 2-methyl-2-propenyl group, a 1-propynyl group, a 1-methyl-1 propynyl group, a 2-propynyl group, a 2-methyl-2-propynyl group, a 1-butenyl group, a 2-butenyl group, a 3-butenyl group, a 1-butynyl group, a 2-butynyl group, or a 3-butynyl group.

As used herein, “aryl group” refers to a substituent in which all atoms (or all ring atoms, e.g., all ring atoms excluding hydrogen and/or other substituents) in the cyclic substituent have a p-orbital and these p-orbitals are conjugated and may include a monocyclic or fused ring polycyclic functional group (e.g., rings sharing adjacent pairs of carbon atoms).

As used herein, “heteroaryl group” refers to an aryl group including at least one heteroatom selected from N, O, S, P, and Si. Two or more heteroaryl groups are linked by a sigma bond directly, or when the heteroaryl group includes two or more rings, the two or more rings may be fused together. When the heteroaryl group is a fused ring, each ring may include one to four heteroatoms.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

Hereinafter, a semiconductor photoresist composition according to some embodiments is described.

The semiconductor photoresist composition according to some embodiments includes an Sn-containing organometallic compound, a carboxylic acid compound, at least one selected from a sulfonic acid compound and a phosphonic acid compound, and a solvent.

The semiconductor photoresist composition can improve sensitivity and LER and achieve excellent resolution by including at least two types (or kinds) of acid compounds such as, for example, a carboxylic acid compound and at least one of selected from sulfonic acid compound and a phosphonic acid compound.

As an example, the carboxylic acid compound: at least one selected from sulfonic acid compound and phosphonic acid compound may be included in a weight ratio of about 1:0.001 to about 1:10.

As an example, the carboxylic acid compound: at least one selected from the sulfonic acid compound and the phosphonic acid compound may be included in a weight ratio of about 1:0.01 to about 1:7.

The carboxylic acid compound may be represented by Chemical Formula 1.

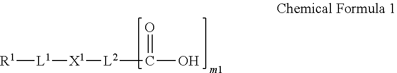

In Chemical Formula 1,
R¹ is an amine group, a halogen, a hydroxy group, a carboxyl group, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a substituted or unsubstituted C7 to C30 arylalkyl group,
L¹ and L² are each independently a single bond (e.g., a single covalent bond), a substituted or unsubstituted C1 to C20 alkylene group, a substituted or unsubstituted C6 to C30 arylene group, or a combination thereof,
X¹ is a single bond (e.g., a single covalent bond), O, S, or NR² (wherein R² is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
m1 is an integer greater than or equal to 1.

The upper limit of m1 may be the maximum value linkable to L², but m1 may be, for example, 1 to 10, 1 to 8, 1 to 6, or 1 to 3 within a range below the maximum value.

The sulfonic acid compound may be represented Chemical Formula 2.

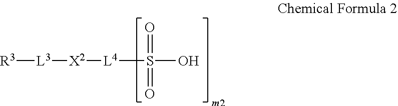

In Chemical Formula 2,
R³ is an amine group, a halogen, a hydroxy group, a carboxyl group, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a substituted or unsubstituted C7 to C30 arylalkyl group,
L³ and L⁴ are each independently a single bond (e.g., a single covalent bond), a substituted or unsubstituted C1 to C20 alkylene group, a substituted or unsubstituted C6 to C30 arylene group, or a combination thereof,
X² is a single bond (e.g., a single covalent bond), O, S, or NR⁴ (wherein R⁴ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
m2 is an integer greater than or equal to 1.

The upper limit of m2 may be the maximum value linkable to L⁴, but m2 may be, for example, 1 to 10, 1 to 8, 1 to 6, or 1 to 3 within a range below the maximum value.

The phosphonic acid compound may be represented by Chemical Formula 3.

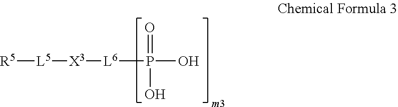

In Chemical Formula 3,
R⁵ is an amine group, a halogen, a hydroxy group, a carboxyl group, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a substituted or unsubstituted C7 to C30 arylalkyl group,
L⁵ and L⁶ are each independently a single bond (e.g., a single covalent bond), a substituted or unsubstituted C1 to C20 alkylene group, a substituted or unsubstituted C6 to C30 arylene group, or a combination thereof,
X³ is a single bond (e.g., a single covalent bond), O, S, or NR⁶ (R⁶ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
m3 is an integer greater than or equal to 1.

The upper limit of m3 may be the maximum value linkable to L⁶, but m3 may be, for example, 1 to 10, 1 to 8, 1 to 6, or 1 to 3 within a range below the maximum value.

For example, R¹, R³, and R⁵ may each independently be a hydroxy group, a carboxyl group, a substituted or unsubstituted methyl group, a substituted or unsubstituted ethyl group, a substituted or unsubstituted propyl group, a substituted or unsubstituted iso-propyl group, a substituted or unsubstituted butyl group, a substituted or unsubstituted iso-butyl group, a substituted or unsubstituted tert-butyl group, a substituted or unsubstituted sec-butyl group, a substituted or unsubstituted pentyl group, a substituted or unsubstituted phenyl group, a substituted or unsubstituted biphenyl group, a substituted or unsubstituted naphthyl group, or a substituted or unsubstituted benzyl group.

For example, L¹ to L⁶ may each independently be a single bond (e.g., a single covalent bond), a substituted or unsubstituted methylene group, a substituted or unsubstituted ethylene group, a substituted or unsubstituted propylene group, a substituted or unsubstituted butylene group, a substituted or unsubstituted pentylene group, a substituted or unsubstituted phenylene group, a substituted or unsubstituted biphenylene group, or a substituted or unsubstituted naphthylene group.

As an example, the carboxylic acid compound may be one of the compounds listed in Group 1.

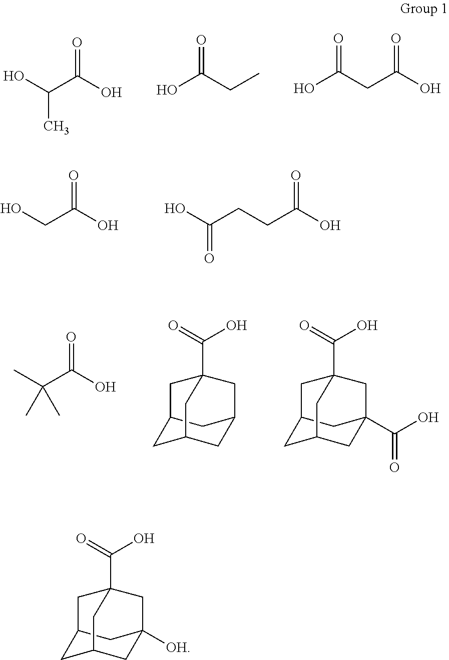

As an example, the sulfonic acid compound and phosphonic acid compound may be one of the compounds listed in Group 2.

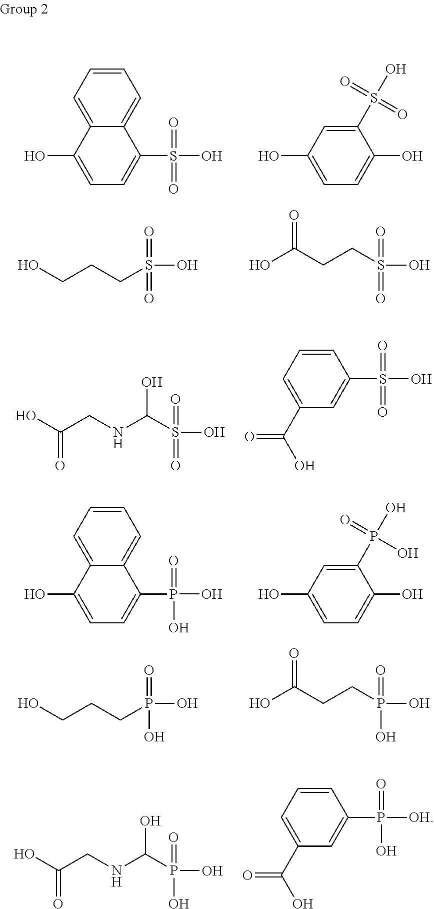

The carboxylic acid compound, and at least one selected from the sulfonic acid compound and the phosphonic acid compound may be included in an amount of 0.001 to 10 wt % based on 100 wt % of the semiconductor photoresist composition.

For example, the carboxylic acid compound, and at least one selected from the sulfonic acid compound and the phosphonic acid compound may be included in an amount of about 0.01 to about 10 wt %, about 0.01 to about 5 wt %, about 0.05 to about 5 wt % or about 0.1 to about 5 wt %, based on 100 wt % of the semiconductor photoresist composition.

The Sn-containing organometallic compound may be included in an amount of about 0.5 wt % to about 30 wt % based on 100 wt % of the semiconductor photoresist composition.

The semiconductor photoresist composition according to some embodiments may improve the sensitivity of the photoresist by including the Sn-containing organometallic compound, the carboxylic acid compound, and at least one selected from the sulfonic acid compound and the phosphonic acid compound within the above content ranges.

The semiconductor photoresist composition according to some embodiments may include the Sn-containing organometallic compound: the carboxylic acid compound and at least one selected from the sulfonic acid compound and the phosphonic acid compound in a weight ratio of about 99:1 to about 80:20. For example, the semiconductor photoresist composition may include the Sn-containing organometallic compound: a carboxylic acid compound and at least one selected from the sulfonic acid compound and phosphonic acid compound in a weight ratio of about 99:1 to about 90:10.

If the weight ratio of the Sn-containing organometallic compound and the acid compound satisfies the above range, a semiconductor photoresist composition having excellent sensitivity can be provided.

The Sn-containing organometallic compound may include at least one selected from an organic oxy group and an organic carbonyloxy group.

The organometallic compound may be a compound represented by Chemical Formula 4 and/or a condensation compound thereof.

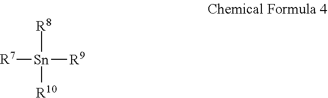

In Chemical Formula 4,
R⁷ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R⁸ to R¹⁰ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, alkoxo and aryloxo (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and/or dialkylamido (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{g}C(NR^{h})Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and/or arylthiol (—SRⁱ, wherein R^{j} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and/or a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof),
at least one selected from R⁸ to R¹⁰ is selected from alkoxo and aryloxo (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and/or dialkylamido (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{g}C(NR^{h}) Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and arylthiol (—SRⁱ, wherein Rⁱ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

At least one selected from R⁸ to R¹⁰ may be selected from alkoxo and aryloxo (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

In embodiments, the compound represented by Chemical Formula 4 includes —OR^{a} and/or —OC(═O)R^{b} as a ligand, so that a pattern formed using a semiconductor photoresist composition including it can exhibit excellent limiting resolution.

In embodiments, the —OR^{a} and/or —OC(═O)R^{b} ligand can determine a solubility of the compound represented by Chemical Formula 4 in a solvent.

R⁷ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{a} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{b} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

R⁷ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof,
R^{a} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and
R^{b} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

In embodiments, the Sn-containing organometallic compound may be represented by Chemical Formula 5 or Chemical Formula 6.

R¹¹_{z}SnO_{(2-(z/2)-(x/2))}(OH)ₓ Chemical Formula 5

In Chemical Formula 5,

R¹¹ is a C1 to C31 hydrocarbyl group, wherein 0<z≤2, 0<(z+x)≤4;

R¹²ₐ₁Sn_{b1}X_{c1}Y_{d1} Chemical Formula 6
wherein, in Chemical Formula 6,
R¹² is a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, ethylene oxide group, propylene oxide group, or a combination thereof,
X is sulfur(S), selenium (Se), or tellurium (Te),
Y is —OR^{l} or —OC(═O)R^{m},
wherein R^{l} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a1, b1, c1, and d1 are each independently an integer in a range from 1 to 20.

The solvent of the semiconductor photoresist composition according to some embodiments may be an organic solvent, and may be for example aromatic compounds (e.g., xylene, toluene, etc.), alcohols (e.g., 4-methyl-2-pentenol, 4-methyl-2-propanol, 1-butanol, methanol, isopropyl alcohol, 1-propanol), ethers (e.g., anisole, tetrahydrofuran), esters (n-butyl acetate, propylene glycol monomethyl ether acetate, ethyl acetate, ethyl lactate), ketones (e.g., methyl ethyl ketone, 2-heptanone), or a mixture thereof, but is not limited thereto.

The semiconductor photoresist composition according to some embodiments may further include a resin in addition to the aforementioned Sn-containing organometallic compound, acid compound, and solvent.

The resin may be a phenolic resin including at least one aromatic moiety of Group 3.

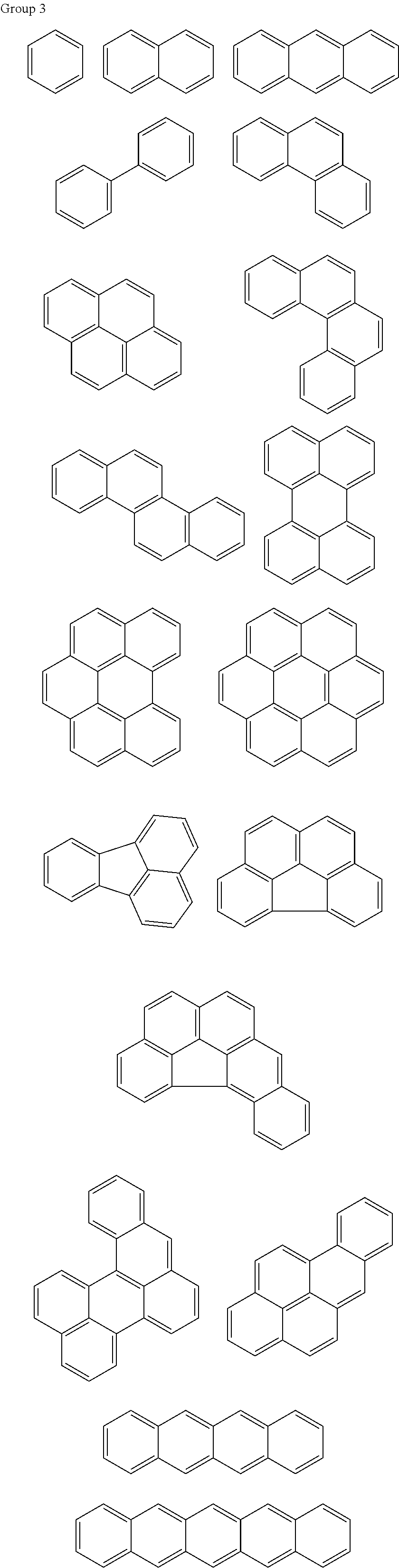

The resin may have a weight average molecular weight of about 500 to about 20,000.

The resin may be included in an amount of about 0.1 wt % to about 50 wt % based on a total amount of the semiconductor photoresist composition.

If the resin is included in the above content range, it may have excellent etch resistance and heat resistance.

In embodiments, the semiconductor photoresist composition may consist of the aforementioned Sn-containing organometallic compound, acid compound, solvent, and resin.

However, the semiconductor photoresist composition according to the aforementioned embodiments may further include additives as needed or desired. Examples of the additives may be a surfactant, a crosslinking agent, a leveling agent, an organic acid, a quencher, or a combination thereof.

The surfactant may include for example an alkyl benzene sulfonate salt, an alkyl pyridinium salt, polyethylene glycol, a quaternary ammonium salt, or a combination thereof, but is not limited thereto.

The crosslinking agent may be for example a melamine-based crosslinking agent, a substituted urea-based crosslinking agent, an acryl-based crosslinking agent, an epoxy-based crosslinking agent, and/or a polymer-based crosslinking agent, but is not limited thereto. The crosslinking agent may have at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, or methoxymethylated thiourea, and/or the like.

The leveling agent may be used for improving coating flatness during printing and may be any suitable leveling agent generally used in the art.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but is not limited thereto.

The quencher may be diphenyl (p-tolyl) amine, methyl diphenyl amine, triphenyl amine, phenylenediamine, naphthylamine, diaminonaphthalene, or a combination thereof.

A use amount of the additives may be controlled depending on suitable or desired properties.

In embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as vinyltrimethoxysilane, vinyl triethoxysilane, vinyl trichlorosilane, vinyl tris(β-methoxyethoxy)silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy [3-(phenylamino)propyl]silane, and/or the like, but is not limited thereto.

The semiconductor photoresist composition may be formed into a pattern having a high aspect ratio without a collapse. Accordingly, in order to form a fine pattern having a width of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be used for a photoresist process using light in a wavelength range from about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to some embodiments may be used to realize extreme ultraviolet lithography using an EUV light source of a wavelength of about 13.5 nm.

According to some embodiments, a method of forming patterns using the aforementioned semiconductor photoresist composition is provided. For example, the manufactured pattern may be a photoresist pattern.

The method of forming patterns according to some embodiments includes forming an etching-objective film on a substrate, coating the semiconductor photoresist composition on the etching-objective film to form a photoresist film, patterning the photoresist film to form a photoresist pattern, and etching the etching-objective film using the photoresist pattern as an etching mask.

The method of forming patterns according to some embodiments includes forming an etching-objective film on a substrate, coating the semiconductor photoresist composition on the etching-objective film to form a photoresist film, patterning the photoresist film to form a photoresist pattern, and etching the etching-objective film using the photoresist pattern as an etching mask.

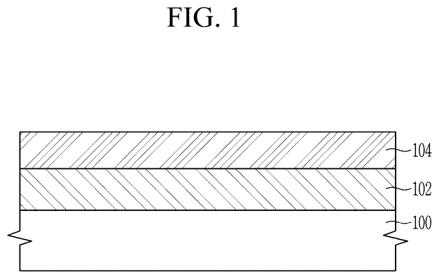

Hereinafter, a method of forming patterns using the semiconductor photoresist composition is described referring to FIGS. 1-5. FIGS. 1-5 are cross-sectional views for explaining a method of forming patterns using a semiconductor photoresist composition according to some embodiments.

Referring to FIG. 1, an object for etching is prepared. The object for etching may be a thin film 102 on a semiconductor substrate 100. Hereinafter, the object for etching is limited to the thin film 102, but the present disclosure is not limited thereto. A surface of the thin film 102 is washed to remove impurities and/or the like remaining thereon. The thin film 102 may be for example a silicon nitride layer, a polysilicon layer, and/or a silicon oxide layer.

Subsequently, the resist underlayer composition for forming a resist underlayer 104 is spin-coated on the surface of the washed thin film 102. However, the embodiment is not limited thereto, and various suitable coating methods, for example a spray coating, a dip coating, a knife edge coating, a printing method, for example an inkjet printing and/or a screen printing, and/or the like may be used.

The coating process of the resist underlayer may be omitted, and hereinafter, a process including a coating of the resist underlayer is described.

Then, the coated composition is dried and baked to form a resist underlayer 104 on the thin film 102. The baking may be performed at about 100° C. to about 500° C., for example, about 100° C. to about 300° C.

The resist underlayer 104 is between the substrate 100 and a photoresist film 106 and thus may prevent or reduce non-uniformity and improve pattern formability of a photoresist line width when a ray reflected from on the interface between the substrate 100 and the photoresist film 106 and/or a hardmask between layers is scattered into an unintended photoresist region.

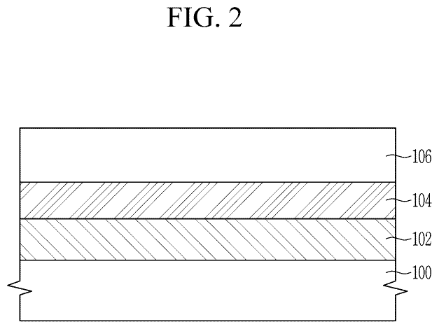

Referring to FIG. 2, the photoresist film 106 is formed by coating the semiconductor photoresist composition on the resist underlayer 104. The photoresist film 106 is obtained by coating the aforementioned semiconductor photoresist composition on the thin film 102 on the substrate 100 and then, curing it through a heat treatment.

In embodiments, the formation of a pattern by using the semiconductor photoresist composition may include coating the semiconductor resist composition on the substrate 100 having the thin film 102 through spin coating, slit coating, inkjet printing, and/or the like and then drying it to form the photoresist film 106.

The semiconductor photoresist composition has already been illustrated and described in detail and may not be illustrated or described again.

Subsequently, a substrate 100 having the photoresist film 106 is subjected to a first baking process. The first baking process may be performed at about 80° C. to about 120° C.

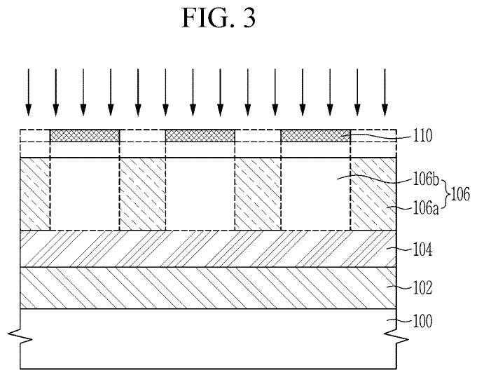

Referring to FIG. 3, the photoresist film 106 may be selectively exposed using a patterned mask 110.

For example, the exposure may use an activation radiation including light having a high energy wavelength such as EUV (extreme ultraviolet; a wavelength of about 13.5 nm), an E-Beam (an electron beam), and/or the like as well as a wavelength such as an i-line (a wavelength of about 365 nm), a KrF excimer laser (a wavelength of about 248 nm), an ArF excimer laser (a wavelength of about 193 nm), and/or the like.

In embodiments, light for the exposure according to some embodiments may have a short wavelength range from about 5 nm to about 150 nm and a high energy wavelength, for example, EUV (extreme ultraviolet; a wavelength of 13.5 nm), an E-Beam (an electron beam), and/or the like.

The exposed region 106a of the photoresist film 106 has a different solubility from the unexposed region 106b of the photoresist film 106 by forming a polymer by a crosslinking reaction such as a condensation reaction between organometallic compounds.

Subsequently, the substrate 100 is subjected to a second baking process. The second baking process may be performed at a temperature of about 90° C. to about 200° C. The exposed region 106a of the photoresist film 106 becomes easily indissoluble regarding a developer due to the second baking process.

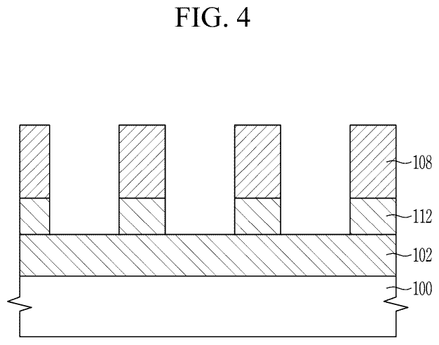

In FIG. 4, the unexposed region 106b of the photoresist film is dissolved and removed using the developer to form a photoresist pattern 108. For example, the unexposed region 106b of the photoresist film is dissolved and removed by using an organic solvent such as 2-heptanone and/or the like to complete the photoresist pattern 108 corresponding to the negative tone image.

As described above, a developer used in a method of forming patterns according to some embodiments may be an organic solvent. The organic solvent used in the method of forming patterns according to some embodiments may be for example ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to some embodiments is not necessarily limited to the negative tone image but may be formed to have a positive tone image. Herein, a developer used for forming the positive tone image may be a quaternary ammonium hydroxide composition such as tetraethylammonium hydroxide, tetrapropyl ammonium hydroxide, tetrabutylammonium hydroxide, or a combination thereof.

As described above, exposure to light having a high energy such as EUV (extreme ultraViolet; a wavelength of 13.5 nm), an E-Beam (an electron beam), and/or the like as well as light having a relatively longer wavelength such as i-line (wavelength of about 365 nm), KrF excimer laser (wavelength of about 248 nm), ArF excimer laser (wavelength of about 193 nm), and/or the like may provide a photoresist pattern 108 having a width of a thickness of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In embodiments, the photoresist pattern 108 may have a pitch of having a half-pitch of less than or equal to about 50 nm, for example less than or equal to about 40 nm, for example less than or equal to about 30 nm, for example less than or equal to about 20 nm, or for example less than or equal to about 15 nm, and a line width roughness of less than or equal to about 10 nm, less than or equal to about 5 nm, less than or equal to about 3 nm, or less than or equal to about 2 nm.

In embodiments, the photoresist pattern 108 is used as an etching mask to etch the resist underlayer 104. Through this etching process, an organic film pattern 112 is formed. The organic film pattern 112 also may have a width corresponding to that of the photoresist pattern 108.

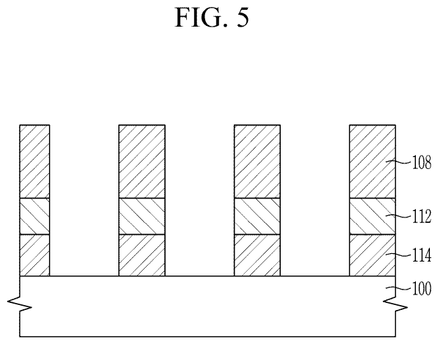

Referring to FIG. 5, the exposed thin film 102 is etched by applying the photoresist pattern 108 as an etching mask. As a result, the thin film is formed as a thin film pattern 114.

The etching of the thin film 102 may be for example dry etching using an etching gas and the etching gas may be for example CHF₃, CF₄, Cl₂, BCl₃, or a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of 5 nm to 100 nm which is equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, or for example a width of less than or equal to about 20 nm, like that of the photoresist pattern 108.

Hereinafter, embodiments of the present disclosure will be described in more detail through examples of the preparation of the aforementioned semiconductor photoresist composition. However, the present disclosure is technically not restricted by the following examples.

### Synthesis of Organometallic Compounds

### Synthesis Example 1

In a 250 ml 2-necked round-bottomed flask, 40.7 g of t-butylSnPhs and 300 g of propionic acid were added and then heated under reflux for 24 hours.

The unreacted propionic acid was removed therefrom under a reduced pressure to obtain a compound represented by Chemical Formula 7.

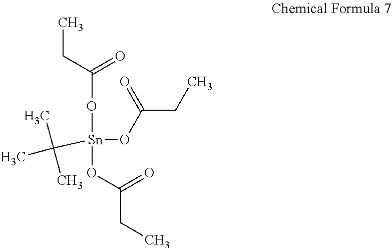 [SMILES: CCC(=O)[O][Sn]([O]C(=O)CC)([O]C(=O)CC)[C](C)(C)C]

### Synthesis Example 2

In a 1L round bottom flask, 18.9 g of iPrSn(NEt₂)₃ was dissolved in 500 mL of anhydrous hexane, the flask was cooled to −78° C., then 9.0 g of iPrOH was slowly added in a dropwise fashion, and a reaction was performed at room temperature for 24 hours. When the reaction was completed, the resultant was concentrated and dried under vacuum to obtain a compound represented by Chemical Formula 8.

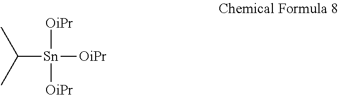 [SMILES: CC(C)[O][Sn]([O]C(C)C)([O]C(C)C)[CH](C)C]

### Synthesis Example 3

After dissolving 10 g of dibutyltin dichloride in 30 mL of ether, 70 mL of a 1 M sodium hydroxide (NaOH) aqueous solution was added thereto and then stirred for 1 hour. After the stirring, a solid produced therein was filtered, three times washed with 25 mL of deionized water, and dried at 100° C. under a reduced pressure to obtain an organometallic compound represented by Chemical Formula 9 and having a weight average molecular weight of 1,500.

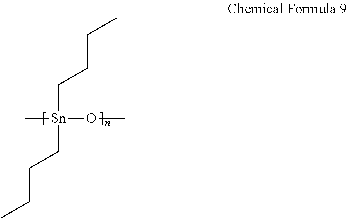

### Preparation of Semiconductor Photoresist Compositions Examples 1 to 9, and Comparative Examples 1 to 3

The organometallic compounds represented by Chemical Formulas 7 to 9 according to Synthesis Examples 1 to 3, a carboxylic acid compound, and a phosphonic acid compound in each weight ratio shown in Table 1 were dissolved in propylene glycol methyl ether acetate (PGMEA) at a concentration of 3 wt % and then filtered with a 0.1 μm PTFE (polytetrafluoroethylene) syringe filter to prepare semiconductor photoresist compositions.

TABLE 1

| | | Acid compound (wt %) | |
|---|---|---|---|
| | Organometallic | Carboxylic | Sulfonic acid or |
| | compound (wt %) | acid | phosphonic acid |
| Comparative | Chemical Formula 7 | C1 | — |
| Example 1 | (2.85) | (0.15) | |
| Comparative | Chemical Formula 7 | — | P1 |
| Example 2 | (2.0) | | (1.0) |
| Comparative | Chemical Formula 7 | — | S1 |
| Example 3 | (2.0) | | (1.0) |
| Example 1 | Chemical Formula 7 | C1 | P1 |
| | (2.35) | (0.15) | 0.5 |
| Example 2 | Chemical Formula 7 | C1 | P1 |
| | (1.85) | (0.15) | (1.0) |
| Example 3 | Chemical Formula 7 | C1 | S1 |
| | (1.85) | (0.15) | (1.0) |
| Example 4 | Chemical Formula 8 | C1 | P1 |
| | (2.35) | (0.15) | 0.5 |
| Example 5 | Chemical Formula 8 | C1 | P1 |
| | (1.85) | (0.15) | (1.0) |
| Example 6 | Chemical Formula 8 | C1 | S1 |
| | (1.85) | (0.15) | (1.0) |
| Example 7 | Chemical Formula 9 | C1 | P1 |
| | 2.35) | (0.15) | 0.5 |
| Example 8 | Chemical Formula 9 | C1 | P1 |
| | (1.85) | (0.15) | (1.0) |
| Example 9 | Chemical Formula 9 | C1 | S1 |
| | (1.85) | (0.15) | (1.0) |

C1: Propionic acid
P1: 3-Phosphonopropanoic acid
S1: 3-Hydroxypropane-1-sulfonic acid

### Evaluation 1: Evaluation of Sensitivity and Line Edge Roughness (LER)

Each of the semiconductor photoresist compositions according to the examples and the comparative examples was spin-coated on a 200 mm circular silicon wafer deposited with hexamethyldisilazane (HMDS) on the surface at 1500 rpm for 30 seconds, fired (post-apply baked (PAB)) at 110° C. for 60 seconds, and allowed to stand at room temperature (23±2° C.) for 30 seconds.

Subsequently, onto the wafer coated with the photoresist composition, a line array of 50 circular pads each having a diameter of 500 μm was projected by using EUV light (Lawrence Berkeley National Laboratory Micro Exposure Tool, MET). Herein, exposure time of the pads was adjusted to apply an increased EUV dose to each pad.

Subsequently, the resist and the substrate were exposed on a hot plate at 160° C. for 120 seconds and then fired. The fired film was developed with a PGMEA solvent to form a negative tone image. Finally, the hot plate was fired at 150° C. for 2 minutes, thereby completing the process.

The exposed pads were measured with respect to a remaining resist thickness by using an ellipsometer. After measuring sensitivity by measuring a remaining thickness for each exposure dose was measured into a graph as its function to the exposure dose and also, LER (line edge roughness) from a field-emission scanning electron microscope (FE-SEM) image, the sensitivity and the line edge roughness were evaluated according to the following criteria, and the results are shown in Table 2.

### Sensitivity Evaluation Criteria

A: less than 16 mJ/cm²
B: greater than or equal to 16 mJ/cm²

### LER Evaluation Criteria

o: less than or equal to 2 nm
Δ: greater than 2 nm and less than or equal to 5 nm
X: greater than 5 nm

### Evaluation 2: Evaluation of Resolution (CD)

After completing the process, a line/space CD pattern was formed on the pattern wafer, which was then transferred to CD-SEM measurement equipment (GC-9380, Hitachi) to measure the CD (Critical Dimension) size of the area where the half-pitch of the mask pattern is 14 nm, and the minimum value among space CDs, which is the distance between lines, are shown in Table 2.

TABLE 2

| | | | Minimum Space |
|---|---|---|---|
| | | | CD |
| | Sensitivity | LER | (@14 nm) |
| Comparative | B | X | 13.3 |
| Example 1 | | | |
| Comparative | B | X | 11.5 |
| Example 2 | | | |
| Comparative | B | X | 12.5 |
| Example 3 | | | |
| Example 1 | A | ◯ | 12.3 |
| Example 2 | A | ◯ | 12.0 |
| Example 3 | A | ◯ | 12.4 |
| Example 4 | A | ◯ | 12.7 |
| Example 5 | A | ◯ | 12.5 |
| Example 6 | A | ◯ | 12.8 |
| Example 7 | A | ◯ | 13.3 |
| Example 8 | A | ◯ | 13.1 |
| Example 9 | A | ◯ | 13.4 |

From the results in Table 2, the patterns formed using the semiconductor photoresist compositions according to Examples 1 to 9 exhibited superior sensitivity, LER, and resolution characteristics compared to the patterns formed using the semiconductor photoresist compositions according to Comparative Examples 1 to 3.

Hereinbefore, example embodiments of the present invention have been described and illustrated, however, it should be apparent to a person having ordinary skill in the art that the present disclosure is not limited to the embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the appended claims, and equivalents thereof.

Description of symbols

| | |
|---|---|
| 100: substrate | 102: thin film |
| 104: resist underlayer | 106: photoresist film |
| 106a: exposed region | 106b: unexposed region |
| 108: photoresist pattern | 112: organic film pattern |
| 110: patterned mask | 114: thin film pattern |

What is claimed is:

1. A semiconductor photoresist composition, comprising:
a Sn-containing organometallic compound;
a carboxylic acid compound;
at least one selected from a sulfonic acid compound and a phosphonic acid compound; and
a solvent.

2. The semiconductor photoresist composition as claimed in claim 1, wherein:
the carboxylic acid compound: the at least one selected from the sulfonic acid compound and the phosphonic acid compound are included in a weight ratio of about 1:0.001 to about 1:10.

3. The semiconductor photoresist composition as claimed in claim 1, wherein:
the carboxylic acid compound is represented by Chemical Formula 1: 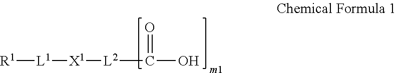
wherein, in Chemical Formula 1, R¹ is an amine group, a halogen, a hydroxy group, a carboxyl group, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a substituted or unsubstituted C7 to C30 arylalkyl group,
L¹ and L² are each independently a single bond, a substituted or unsubstituted C1 to C20 alkylene group, a substituted or unsubstituted C6 to C30 arylene group, or a combination thereof,
X¹ is a single bond, O, S, or NR² (wherein R² is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
m1 is an integer greater than or equal to 1.

4. The semiconductor photoresist composition as claimed in claim 1, wherein:
the sulfonic acid compound is represented by Chemical Formula 2: 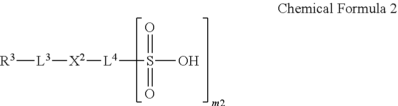
wherein, in Chemical Formula 2,
R³ is an amine group, a halogen, a hydroxy group, a carboxyl group, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a substituted or unsubstituted C7 to C30 arylalkyl group,
L³ and L⁴ are each independently a single bond, a substituted or unsubstituted C1 to C20 alkylene group, a substituted or unsubstituted C6 to C30 arylene group, or a combination thereof,
X² is a single bond, O, S, or NR⁴ (wherein R⁴ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
m2 is an integer greater than or equal to 1.

5. The semiconductor photoresist composition as claimed in claim 1, wherein:
the phosphonic acid compound is represented by Chemical Formula 3: 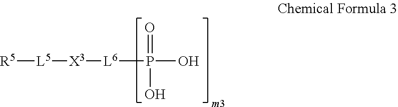
wherein, in Chemical Formula 3,
R⁵ is an amine group, a halogen, a hydroxy group, a carboxyl group, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a substituted or unsubstituted C7 to C30 arylalkyl group,
L⁵ and L⁶ are each independently a single bond, a substituted or unsubstituted C1 to C20 alkylene group, a substituted or unsubstituted C6 to C30 arylene group, or a combination thereof,
X³ is a single bond, O, S, or NR⁶ (wherein R⁶ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
m3 is an integer greater than or equal to 1.

6. The semiconductor photoresist composition as claimed in claim 1, wherein
the carboxylic acid compound is at least one selected from the compounds listed in Group 1:

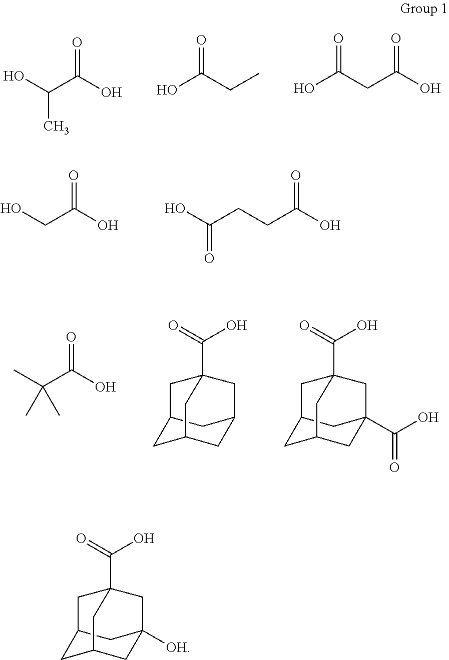

7. The semiconductor photoresist composition as claimed in claim 1, wherein:
the sulfonic acid compound and the phosphonic acid compound are at least one of the compounds listed in Group 2:

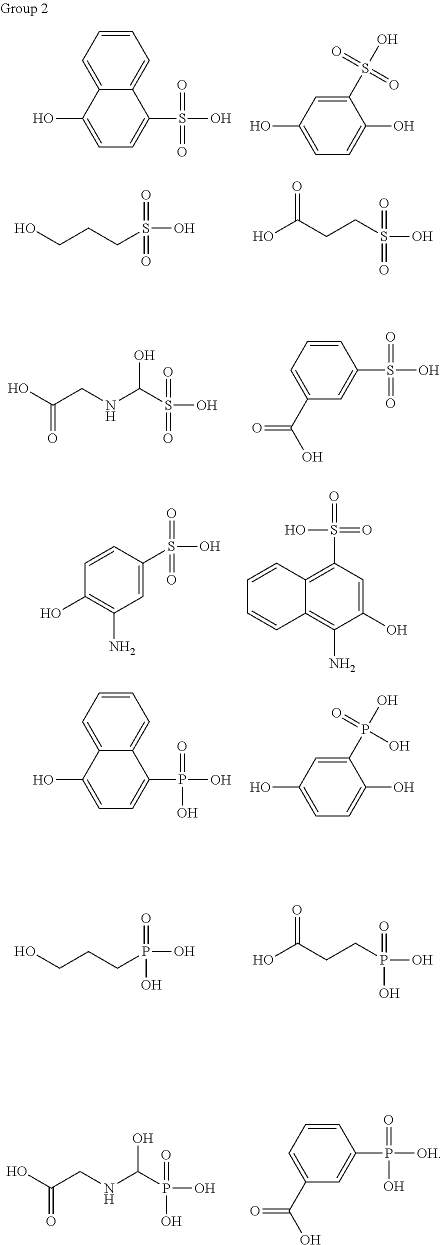

8. The semiconductor photoresist composition as claimed in claim 1, wherein:
the carboxylic acid compound and the at least one selected from the sulfonic acid compound and the phosphonic acid compound are included in an amount of about 0.001 to about 10 wt % based on 100 wt % of the semiconductor photoresist composition.

9. The semiconductor photoresist composition as claimed in claim 1, wherein:
the carboxylic acid compound and the at least one selected from the sulfonic acid compound and the phosphonic acid compound are included in an amount of about 0.1 to about 5 wt % based on 100 wt % of the semiconductor photoresist composition.

10. The semiconductor photoresist composition as claimed in claim 1, wherein:
the Sn-containing organometallic compound is included in an amount of about 0.5 wt % to about 30 wt % based on 100 wt % of the semiconductor photoresist composition.

11. The semiconductor photoresist composition as claimed in claim 1, wherein:
the semiconductor photoresist composition further comprises an additive of a surfactant, a crosslinking agent, a leveling agent, an organic acid, a quencher, or a combination thereof.

12. The semiconductor photoresist composition as claimed in claim 1, wherein:
the Sn-containing organometallic compound comprises at least one selected from an organic oxy group and an organic carbonyloxy group.

13. The semiconductor photoresist composition as claimed in claim 1, wherein:
the Sn-containing organometallic compound is a compound represented by Chemical Formula 4 or a condensation compound thereof: 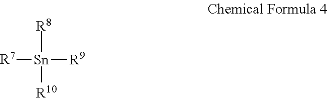
wherein, in Chemical Formula 4,
R⁷ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R⁸ to R¹⁰ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, alkoxo and/or aryloxo (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and/or dialkylamido (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NRₑ(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{g}C(NR^{h})Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and/or arylthiol (—SR^{j}, wherein R^{j} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) and/or a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof),
at least one selected from R⁸ to R¹⁰ is selected from alkoxo and aryloxo (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and dialkylamido (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{g}C(NR^{h})Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and arylthiol (—SR^{j}, wherein R^{j} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) and a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

14. The semiconductor photoresist composition as claimed in claim 13, wherein:
at least one selected from R⁸ to R¹⁰ is selected from alkoxo and aryloxo (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

15. The semiconductor photoresist composition as claimed in claim 13, wherein:
R⁷ is a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{a} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{b} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

16. The semiconductor photoresist composition as claimed in claim 1, wherein:
the Sn-containing organometallic compound is represented by Chemical Formula 5 or Chemical Formula 6:
R¹¹_{z}SnO_{(2-(z/2)-(x/2))}(OH)ₓ Chemical Formula 5
wherein, in Chemical Formula 5,
R¹¹ is a C1 to C31 hydrocarbyl group, wherein 0<z≤2, 0<(z+x)≤4;
R¹²ₐ₁Sn_{b1}X_{c1}Y_{d1} Chemical Formula 6
wherein, in Chemical Formula 6,
R¹² is a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, ethylene oxide group, propylene oxide group, or a combination thereof,
X is sulfur(S), selenium (Se), or tellurium (Te),
Y is —OR^{l} or —OC(═O)R^{m},
wherein R^{l} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a1, b1, c1, and d1 are each independently an integer in a range from 1 to 20.

17. A method of forming patterns, comprising:
providing an etching-objective film on a substrate;
coating the semiconductor photoresist composition as claimed in claim 1 on the etching-objective film to form a photoresist film;
patterning the photoresist film to form a photoresist pattern; and
etching the etching-objective film using the photoresist pattern as an etching mask.
